(19) United States
(12) Patent Application Publication
(10) Pub. No.: US 2024/0114267 A1
(43) Pub. Date: Apr. 4, 2024

(54) MINIATURE NETWORK INTERFACE DEVICE

(71) Applicant: viaPhoton, Inc., Aurora, IL (US)

(72) Inventor: Mark James SMRHA, Chicago, IL (US)

(73) Assignee: viaPhoton, Inc., Aurora, IL (US)

(21) Appl. No.: 18/373,825

(22) Filed: Sep. 27, 2023

Related U.S. Application Data
(60) Provisional application No. 63/411,577, filed on Sep. 29, 2022.

(51) Int. Cl. H04Q 1/02; H05K 5/02; H05K 5/03

(52) U.S. Cl. CPC H04Q 1/023; H05K 5/0247; H05K 5/03

(57) ABSTRACT

An apparatus implements a miniature network interface device. The apparatus includes an outer housing and a tray assembly that includes a sliding tray and a tray insert. The tray assembly is removable from the outer housing. The apparatus further includes the tray insert secured to the sliding tray to form the tray assembly and the sliding tray configured to receive one or more cables routed within the outer housing with the tray insert.

### CROSS REFERENCE TO RELATED APPLICATIONS

This application claims the benefit of U.S. Provisional Application 63/411,577, filed Sep. 29, 2022, which is incorporated by reference herein.

### BACKGROUND

Service providers deploy communications equipment to provide communication services to different locations. The locations include commercial and residential buildings and structures. Challenges with providing communication services include demarcation, environmental protection, security, maintenance, etc.

### SUMMARY

In general, in one or more aspects, the disclosure relates to an apparatus implementing a miniature network interface device. The apparatus includes an outer housing and a tray assembly that includes a sliding tray and a tray insert. The tray assembly is removable from the outer housing. The apparatus further includes the tray insert secured to the sliding tray to form the tray assembly and the sliding tray configured to receive one or more cables routed within the outer housing with the tray insert.

In general, in one or more aspects, the disclosure relates to a system forming a network interface device. The system includes a splice sleeve, a coupler, and a tray assembly to which the splice sleeve and the couple are secured, and an outer housing. The tray assembly includes a sliding tray and a tray insert. The tray assembly is removable from the outer housing. The tray insert is secured to the sliding tray to form the tray assembly. The sliding tray is configured to receive one or more cables routed within the outer housing with the tray insert.

In general, in one or more aspects, the disclosure relates to a method of a miniature network interface device. The method includes securing a cable to a tray insert in a sliding tray of a tray assembly. The tray assembly includes the sliding tray and a tray insert. The tray assembly is removable from an outer housing. The tray assembly further includes the tray insert secured to the sliding tray to form the tray assembly and the sliding tray configured to receive one or more cables routed within the outer housing with the tray insert. The method further includes securing the tray assembly to the outer housing.

Other aspects of the one or more embodiments will be apparent from the following description and the appended claims.

### BRIEF DESCRIPTION OF DRAWINGS

FIG. 1 shows a system, in accordance with one or more embodiments of the disclosure.

FIG. 2 shows a method in accordance with one or more embodiments of the disclosure.

FIG. 3, FIG. 4.1, FIG. 4.2, FIG. 4.3, FIG. 5, FIG. 6, FIG. 7, FIG. 8, FIG. 9.1, FIG. 9.2, FIG. 10, FIG. 11, FIG. 12, FIG. 13.1, and FIG. 13.2 show examples in accordance with one or more embodiments of the disclosure.

Like elements in the various figures are denoted by like reference numerals for consistency.

### DETAILED DESCRIPTION

In general, one or more embodiments address the challenges of demarcation, environmental protection, security, maintenance, etc., by the use of a network interface device (NID) that has been miniaturized. Network interface device, which may be used by the telecommunications industry, distribute service to the locations of customers. Network interface devices form a demarcation point between a network of a customer and to a carrier network of the service provider. A network interface device may also be referred to as an optical network terminal, a fiber electronics box, an internet connection box, a network interface unit, a system network interface, a telephone network interface, etc.

A network interface device is a piece of equipment that includes an enclosure that may be mounted to an outside wall (or inside wall) of buildings and structures at a location. Network interface devices may be used with copper or fiber networks and may allow one or many connections to the network of the service provider. Network interface devices may be used on single family homes or multi-dwelling units (MDUs), such as apartment buildings, condominiums, townhomes, etc.

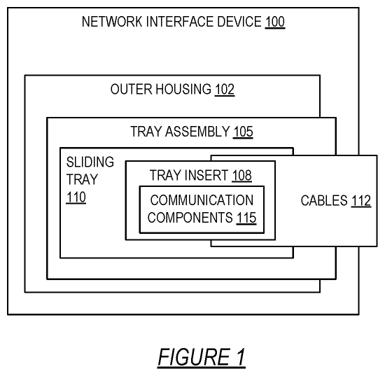

Turning to FIG. 1, the network interface device (100) is a device suitable for outdoor use that protects a connection between the communication network of a service provider and the local network at a location. The components protected within the network interface device (100) include the communication components (115), which may include splices, connectors, cables, etc. The network interface device (100) includes the outer housing (102).

The outer housing (102) is an exterior cover for the network interface device (100). In one embodiment, the outer housing (102) is made of a rigid plastic material. The outer housing (102) protects the communication components within the network interface device (100) from the environment. The outer housing (102) is structured to receive the tray assembly (105).

The tray assembly (105) is the collection of structures and components that fit within the outer housing (102). The tray assembly (105) includes the tray insert (108) and the sliding tray (110). The tray assembly (105) is structured to slide into the outer housing (102).

The tray insert (108) is an insert that fits within the sliding tray (110). The tray insert (108) secures the communications components within the network interface device (100), including the cables (112).

The cables (112) are communications cables, which may include electrical cables, fiber optic cables, etc. The cables (112) may be wound around a perimeter of the tray insert (108). The cables (112) extend from the exterior of the network interface device (100) into the sliding tray (110) may run into an interior of the tray insert (108) to connect with the communication components (115), which may include splices, couplers, connectors, etc.

The sliding tray (110) is a tray of the network interface device (100) into which the tray insert (108) is inserted and which slides into the outer housing (102). The sliding tray (110) protects the tray insert (108) and the communication components (115) from the rigors of sliding into and out of the outer housing (102).

The communication components (115) the components to which the cables (112) are connected. The communication components (115) connect the service provider network to the network at the location where network interface device (100) is installed. The communication components (115) may include splices, couplers, connectors, etc. A splice is a junction where two optical fibers from the cables (112) are joined together to enable the transmission of light signals between the two optical fibers. A coupler combines or splits communication signals between communication cables to allowing the transmission of communication signals to multiple paths or the consolidation of signals from different sources. A connector is a device that enables the physical connection of communication cables to facilitate the transmission of communication signals.

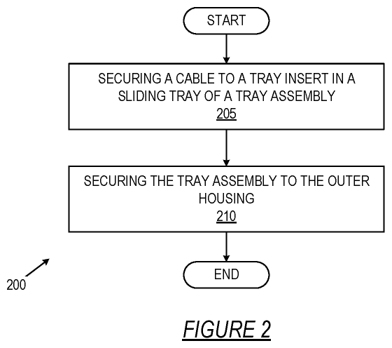

Turning to FIG. 2, the method disclosed assembles a network interface device. The network interface device may be fully or partially assembled prior to being installed at a location.

At Step 205, the method includes securing a cable to a tray insert in a sliding tray of a tray assembly. Securing a cable to a tray insert in a sliding tray of a tray assembly may include the cable being secured to the tray insert to ensure stability and organization. The tray insert may be removed from the sliding tray to provide easy access to the tray insert. The tray insert may include cable management features that are designated points or slots used for cable management. The cable management features may include clips, hooks, tie-down points, etc. The cable is arranged along the tray insert to follow a path or arrangement to prevent tangling or interference with other cables. The cable is secured to the tray insert using the cable management features and maintaining a clean and organized cable routing within the sliding tray to maintain system integrity and minimize the risk of cable-related issues within the tray assembly. The tray insert may then be reinserted and secured to the sliding tray.

At Step 210, the method includes securing the tray assembly to the outer housing. Securing the tray assembly to the outer housing of a network interface device involves the attachment of the tray assembly to the outer housing in a secure manner. The mounting features (brackets, rails, guides, etc.) on the tray assembly are aligned with corresponding mounting features within the outer housing. The sliding tray of the tray assembly is slid into the outer housing. In one embodiment, the tray assembly is secured to the outer housing with a compression fitting that includes an environmental seal to protect the components within the network interface device.

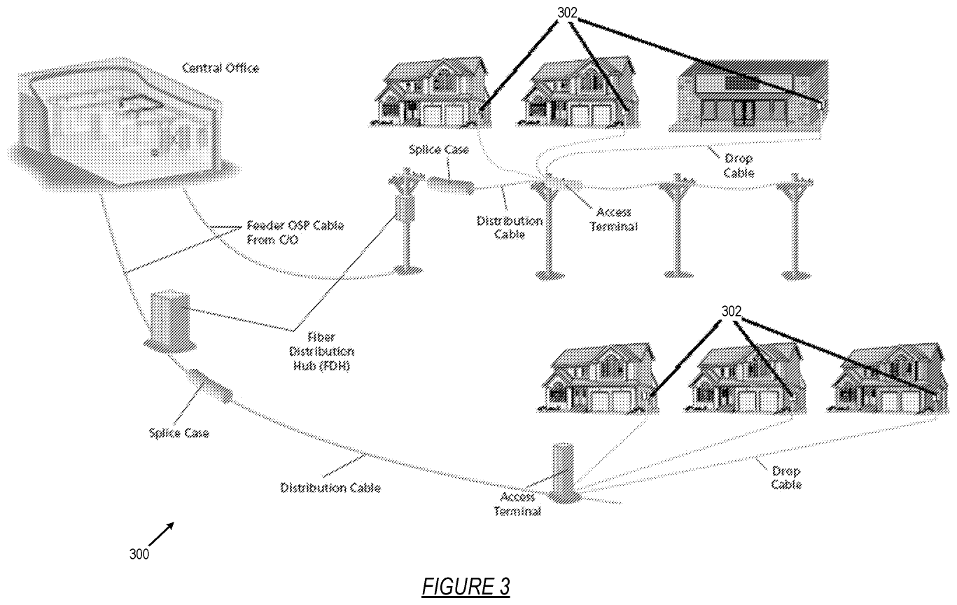

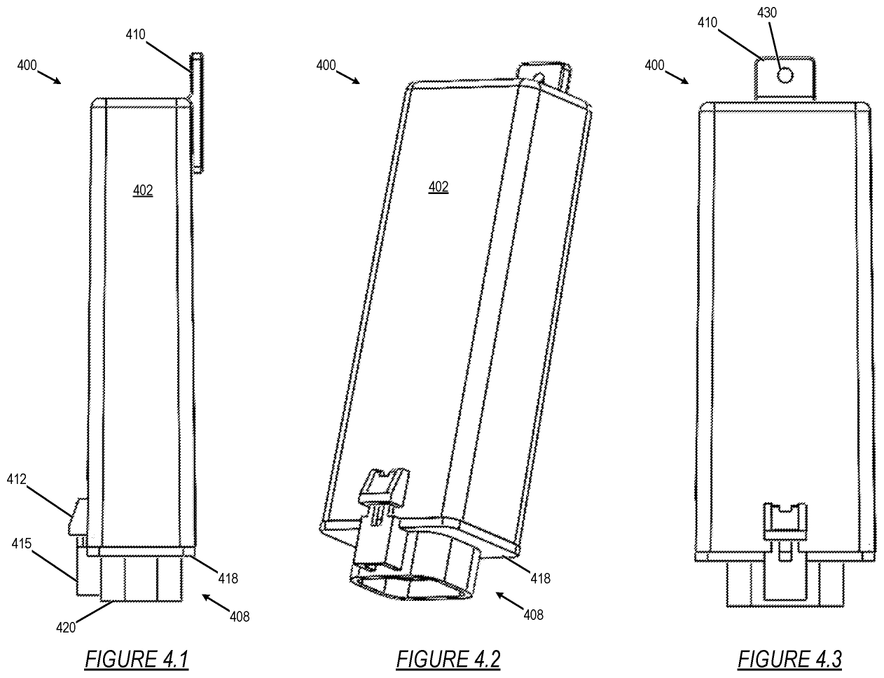

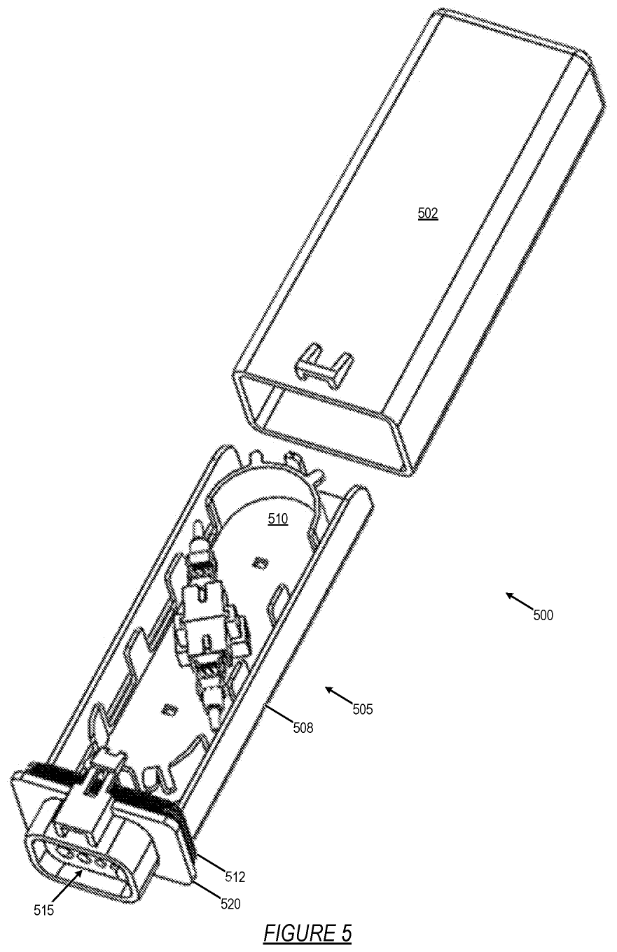

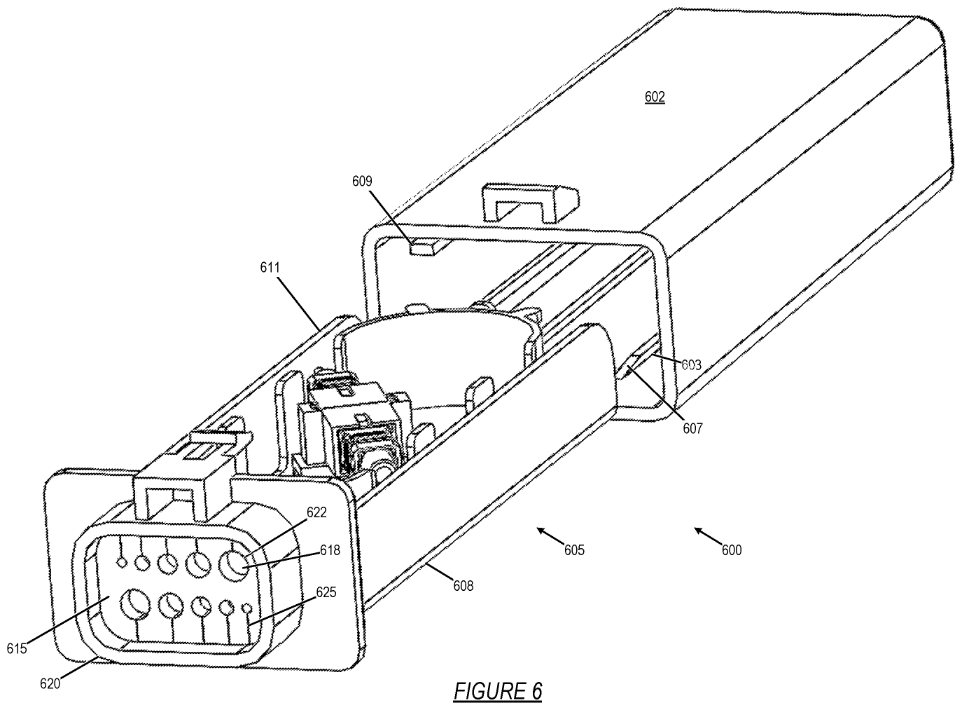

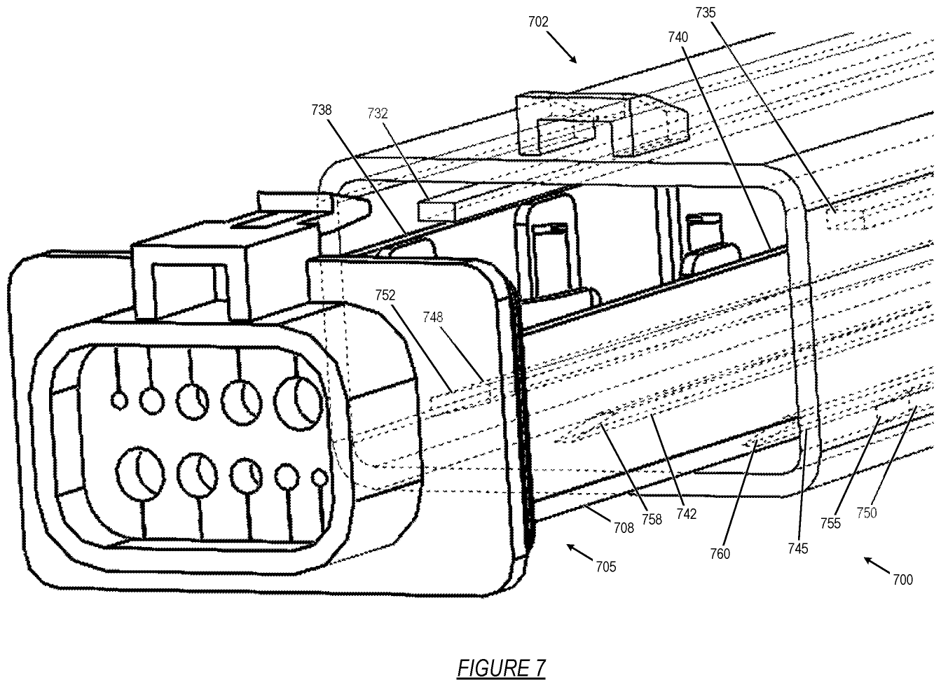

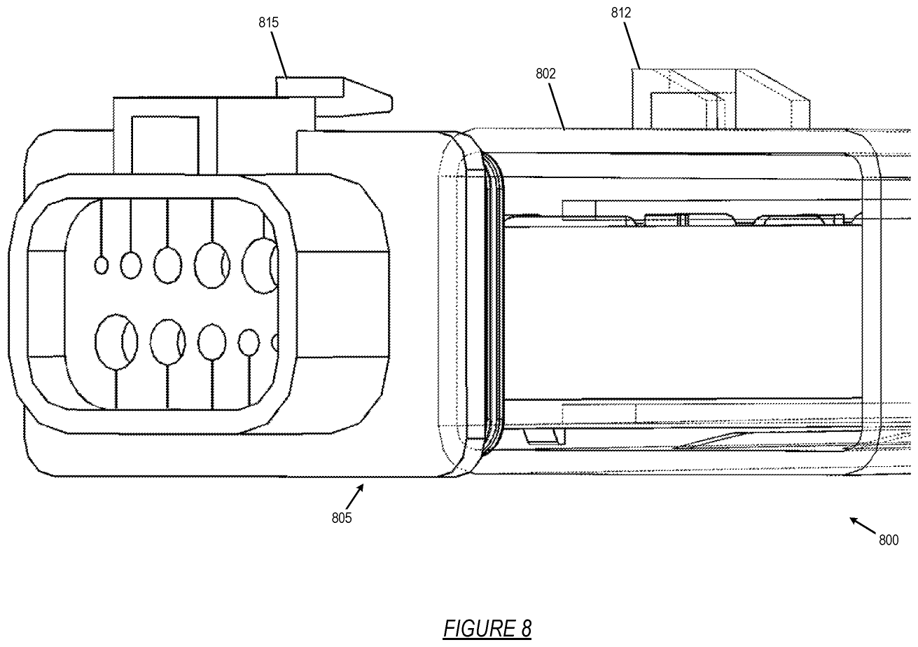

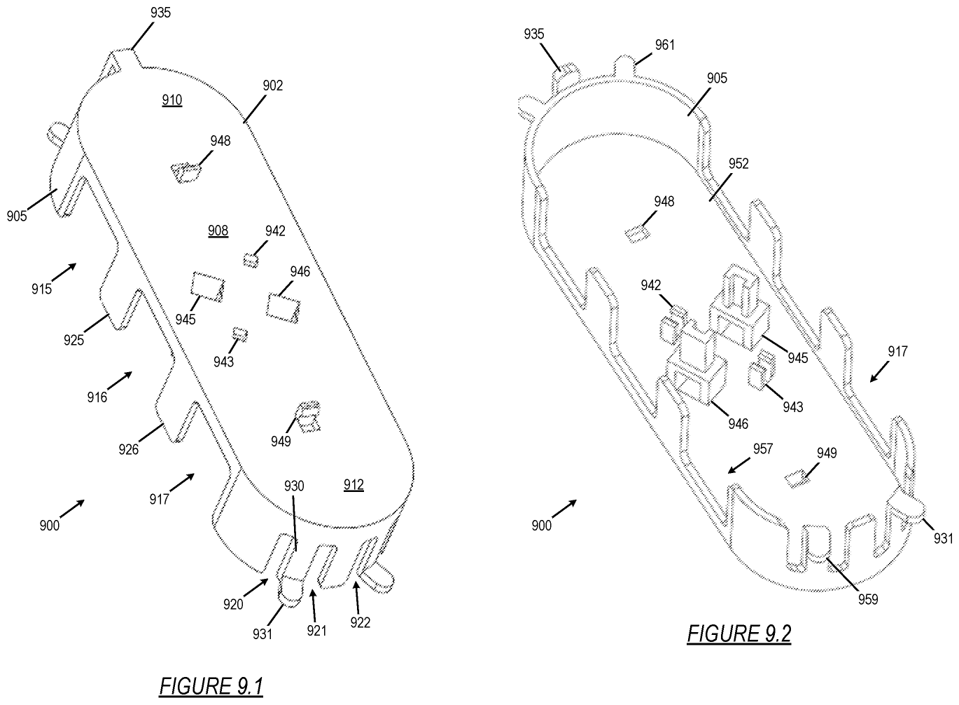

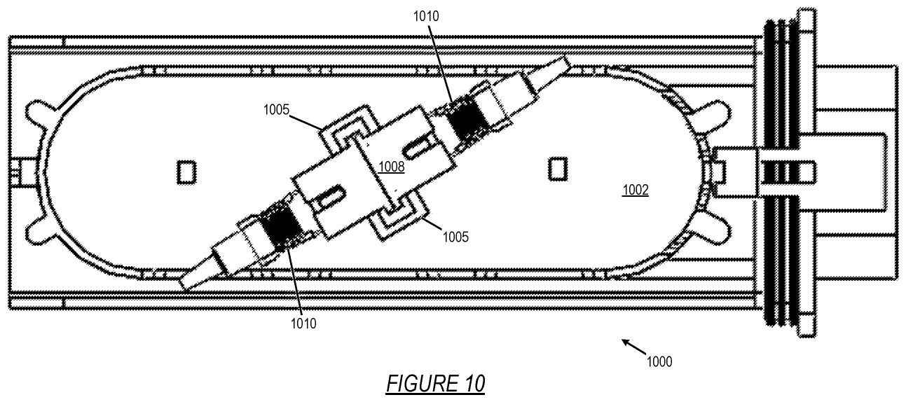

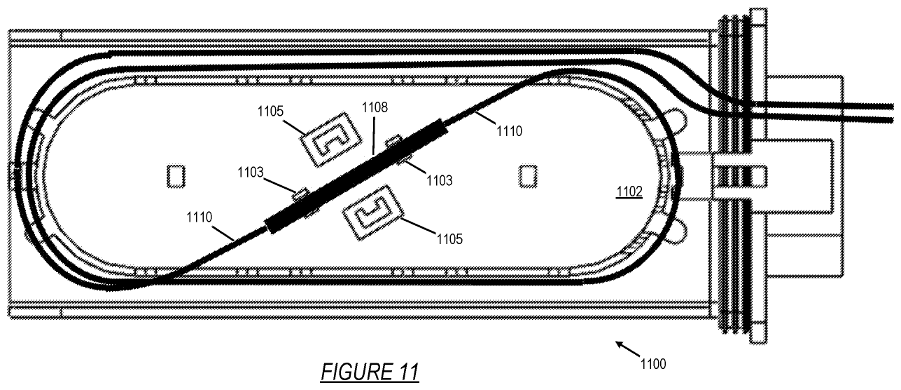

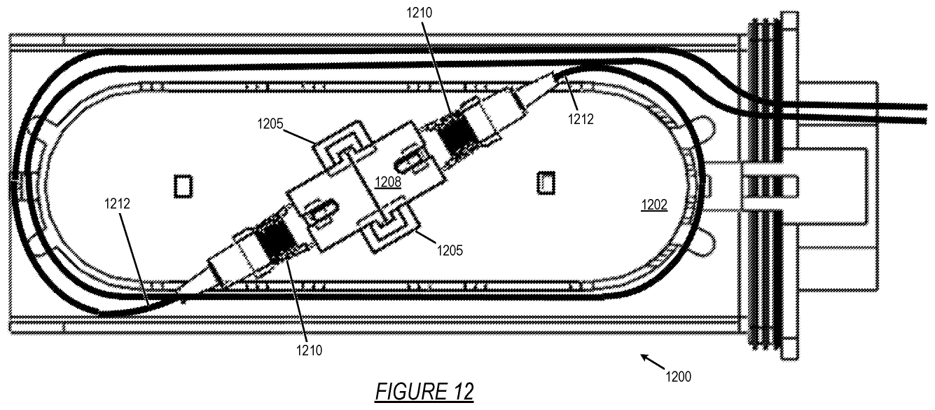

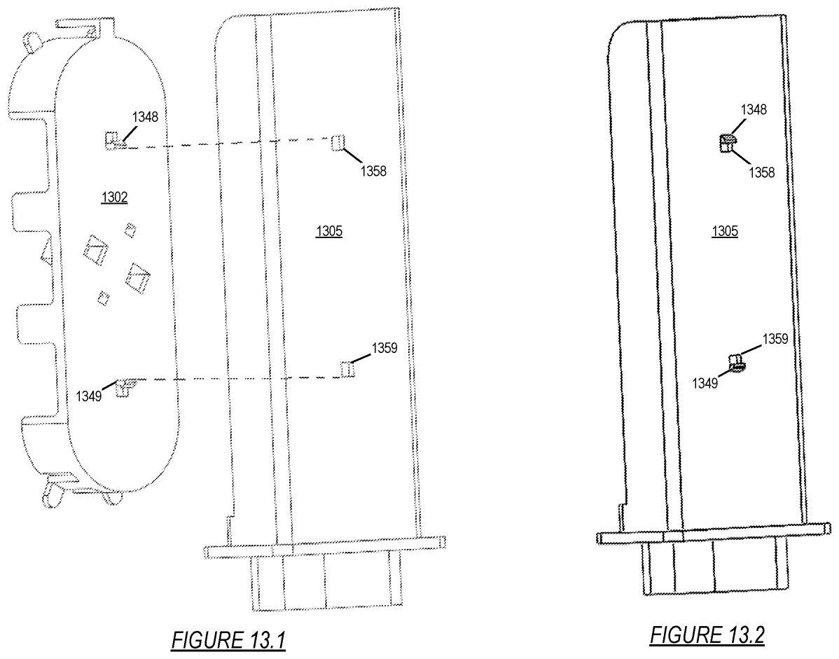

Turning to FIG. 3, the communication network (300) includes the physical network of a service provider that is connected through the network interface devices (302) to the multiple local networks at different locations. The physical network of the service provider may include several lengths of cable, access terminals, splices, etc., to bring communication signals from a central office of the service provider to the locations being served.

FIGS. 4.1, 4.2, and 4.3 depict the network interface device (400). FIG. 4.1 depicts a side view of the network interface device (400). FIG. 4.2 depicts a perspective view of the top and side of the network interface device (400). FIG. 4.3 depicts a top view of the network interface device (400).

Turning to FIG. 4.1, the network interface device (400) protects communication components and includes several elements. The network interface device (400) includes the outer housing (402) and the sliding tray (408).

The outer housing (402) includes the mounting bracket (410) and the fastening member (415). The outer housing (402) protects the components within the network interface device (400) from environmental conditions, including wind, rain, etc.

The mounting bracket (410) is used to mount the network interface device (400) at a location. In one embodiment, the mounting bracket (410) is integrally formed as part of the outer housing (402). In one embodiment, the mounting bracket (410) is formed on the outer housing (402) at an end opposite from an open end of the outer housing (402) into which the sliding tray (408) is inserted.

The fastening member (412) of the outer housing (402) is used in conjunction with the fastening member (415) of the sliding tray (408) to secure the sliding tray (408) to the outer housing (402). The fastening member (412) may be integrally formed as part of the outer housing (402).

The sliding tray (408) is fitted to the outer housing (402). The sliding tray (408) includes the fastening member (415), the flange (418), and the extension (420).

The fastening member (415) of the sliding tray (408) is used in conjunction with the fastening member (412) of the outer housing (402) to secure the sliding tray (408) to the outer housing (402). The fastening member (415) may be integrally formed as part of the sliding tray (408).

The extension (420) is an extension from the flange (418). The extension (420) provides an opening in the sliding tray (408) through which cables may pass from the exterior to the interior. In one embodiment, the fastening member (415) of the sliding tray (408), the flange (418), and the extension (420) may be integrally formed at proximal end of the sliding tray (408).

Turning to FIG. 4.2, the network interface device (400) includes the flange (418). The flange (418) separates an inner portion of the sliding tray (408) that slides into the outer housing (402) from an exterior portion of the sliding tray (408) that remains outside of the outer housing (402).

Turning to FIG. 4.3, the mounting bracket (410) includes the mounting hole (430). The mounting hole (430) may receive a fastener (e.g., a bolt, a nail, a screw, etc.) to secure the network interface device (400) to a structure.

Turning the FIG. 5, the network interface device (500) is configured to protect and route cables, which may include optical fiber cables. The network interface device (500) protects the cables from outdoor environmental conditions. The network interface device (500) includes the outer housing (502) and the tray assembly (505). The outer housing (502) may be made with a rigid material, including plastic, metal, wood, etc.

The tray assembly (505) includes the sliding tray (508) and the tray insert (510). The sliding tray (508) is configured to receive one or more cables routed within the outer housing (502) with the tray insert (510). The tray insert (510) is secured to the sliding tray (508) to form the tray assembly (505). The tray assembly (505) is removable from the outer housing (502). The sliding tray (508) and the tray insert (510) may be made with a rigid material, including plastic, metal, wood, etc.

In one embodiment, the sliding tray (508) includes the sliding tray seal (512). The sliding tray seal (512) may be made from a soft material, including rubber, elastomer, soft plastic, etc. The sliding tray seal (512) may be wrapped around an extrusion from the flange (520) that extends into the outer housing (502) when the flange (520) is pressed against the outer housing (502).

In one embodiment, the sliding tray (508) includes the cable grommet seal (515). The cable grommet seal (515) may be made from a soft material, including rubber, elastomer, soft plastic, etc.

Turning to FIG. 6, the network interface device (600) is illustrated in an exploded view with the tray assembly (605) outside of the outer housing (602). The interior of the outer housing (602) includes several mounting features to align and provide tension to the sliding tray (608) of the tray assembly (605) to secure the sliding tray (608) within the outer housing (602).

The mounting features include the lower guide (603) on a bottom surface of the interior of the outer housing (602). The lower guide (603) includes the ramp (607) to facilitate the insertion of the sliding tray (608) into the outer housing (602).

The mounting features further include the upper guide (609) on a top surface of the interior of the outer housing (602). When the sliding tray (608) is inserted into the outer housing (602), the upper guide (609) compresses against the side wall (611) of the sliding tray (608). The upper guide (609) in conjunction with the lower guide (603) provide support an axis (e.g., a vertical axis) of the network interface device (600).

The sliding tray (608) includes the extension (620), which includes the grommet seal (615). The grommet seal (615) includes several holes (622) of varying diameters. The holes (622) further include the splits (625) to provide for the passing of pre-terminated cables in which the cross-sectional area of the termination on the cable may be greater than the cross-sectional are of the cable and corresponding hole in the grommet seal (615).

In one embodiment, the membrane (618) is behind the grommet seal (615) to cover the holes (622). During installation, the membrane (618) may be punctured to pass one or more cables through one the holes (622).

Turning to FIG. 7, a partially transparent upper side perspective view of the network interface device (700) is shown with dotted lines indicating features occluded behind other features. The network interface device (700) is illustrated in an exploded view with the tray assembly (705) partially within the outer housing (702).

The upper guides (732) and (735) press down on the top surfaces of the side walls (738) and (740). The lower guides (742) and (745) push up on a bottom exterior surface of the sliding tray (708). Force from the upper guides (732) and (735) and the lower guides (742) and (745) onto the sliding tray (708) secure the sliding tray (708) along a first axis (e.g., a vertical axis) of the network interface device (700).

The lateral guides (748) and (750) press against the exterior sides of the side walls (738) and (740). Force from the lateral guides (748) and (750) onto the sliding tray (708) secure the sliding tray (708) along a second axis (e.g., a horizontal axis) of the network interface device (700). In one embodiment, the second axis is orthogonal to the first axis. The lateral guides (748) and (750) include the ramps (752) and (755), which may be longer than the ramps (758) and (760) of the lower guides (742) and (745).

Turning to FIG. 8, a partially transparent side perspective view of the network interface device (800) is shown with dotted lines indicating features occluded behind other features. The network interface device (800) is illustrated in an exploded view with the tray assembly (805) partially within the outer housing (802).

The fastening member (815) of the sliding tray (808) snaps and fits into the fastening member (812) of the outer housing (802) to secure the tray assembly (805) to the outer housing (802). Securing the tray assembly (805) to the outer housing (802) with the fastening members (812) and (815) prevents longitudinal movement of the tray assembly (805) with respect to the outer housing (802).

FIGS. 9.1 and 9.2 depict the tray insert (900). FIG. 9.1 depicts a bottom perspective view of the tray insert (900). FIG. 9.2 depicts a top perspective view of the tray insert (900).

Turning to FIG. 9.1, the tray insert (900) includes the exterior bottom surface (902) from which the perimeter wall (905) extends. In one embodiment, the tray insert (900) is formed as an elongated circular structure with an elongated medial section (908) capped by two semicircular ends (910) and (912). Different shapes may be used. The semicircular end (910) corresponds to a distal end of the tray insert (900) and the semicircular end (912) corresponds to a proximal end of the tray insert (900).

The perimeter wall (905) outlines a perimeter of the tray insert (900). The perimeter wall (905) includes the wall gaps (915), (916), and (917) (also referred to as medial wall gaps) in the medial section (908) and includes the wall gaps (920), (921), and (922) (also referred to as lateral wall gaps) in the semicircular end (912). The medial wall gaps (915) and (916) are separated by the wall portion (925), and the medial wall gaps (916) and (917) are separated by the wall portion (926). The wall gaps (920) and (921) are separated by the wall portion (930) which includes the tab (931). The depth of the wall gaps may differ. For example, the medial wall gap (916) is cut to a lower depth than the lateral wall gap (920). The wall gaps provide for the passage of cables between the interior and exterior of the tray insert (900).

The end retainer (935) extends from the bottom surface (902) of the tray insert (900). The end retainer (935) is a cable management feature that works in conjunction with the corresponding portion of the perimeter wall (905) to prevent movement of cables wrapped around the tray insert (900).

The tray insert (900) includes the attachment features (948) and (949). The attachment features (948) and (949) are used to attach the tray insert (900) to a sliding tray (e.g., the sliding tray (608) of FIG. 6). The support features (942), (943), (945), and (946) may be identified from openings on the exterior bottom surface (902).

Turning to FIG. 9.2, the tray insert (900) includes the attachment features (948) and (949) that may be identified from openings on the interior bottom surface (952). The support features (942) and (943) form retainers to support a splice. The support features (945) and (946) form retainers to support a coupler. The perimeter wall (905) includes the wall gap (917) that corresponds to the wall gap (957) on an opposite side. The tab (931) is mirrored by the tab (959) across a longitudinal axis of the tray insert (900) and is mirrored by the tab (961) across a latitudinal axis of the tray insert (900). The end retainer (935) extends up to the same height as the perimeter wall (905).

Turning to FIG. 10, the sliding tray (1000) of a network interface device is shown. The sliding tray (1000) includes the tray insert (1002). The tray insert (1002) includes the coupler retainers (1005) into which the coupler (1008) is affixed. Into the coupler (1008), the connectors (1010) are installed. Into connectors (1010), cables (not shown) may be installed.

Turning to FIG. 11, the sliding tray (1100) of a network interface device is shown. The sliding tray (1100) includes the tray insert (1102). The tray insert (1102) includes the splice retainers (1103) and the coupler retainers (1105). The splice retainers (1103) secure the splice (1108). The splice (1108) splices together the two cables (1110), which are data communication cables and may be fiber optic cables. The cables (1110) wrap around the tray insert (1102).

Turning to FIG. 12, the sliding tray (1200) of a network interface device is shown. The sliding tray (1200) includes the tray insert (1202). The tray insert (1202) includes the coupler retainers (1205) into which the coupler (1208) is affixed. Into the coupler (1208), the connectors (1210) are installed. Into the connectors (1210), the cables (1212) are installed. The cables (1212) wrap around the tray insert (1202).

FIGS. 13.1 and 13.2 illustrate attaching the tray insert (1302) to the sliding tray (1305). Turning to FIG. 13.1, tray insert (1302) includes the attachment features (1348) and (1349) that align with the attachment features (1358) and (1359) of the sliding tray (1305). Turning to FIG. 13.2, the attachment features (1348) and (1349) of the tray insert (1302) (shown in FIG. 13.1 and occluded by the sliding tray (1305) in FIG. 13.2) have been snapped in and secured to the attachment features (1358) and (1359) of the sliding tray (1305) to secure the tray insert (1302) to the sliding tray (1305).

The various descriptions, features, and elements of the figures may be combined and may include or be included within the features described in the other figures of the application. Similarly named features and elements between different figures may refer to the same feature or element. The various elements, systems, components, and steps shown in the figures may be omitted, repeated, combined, and/or altered as shown from the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Further, unless expressly stated otherwise, the word “or” is an “inclusive or” and, as such includes “and.” Further, items joined by an or may include any combination of the items with any number of each item unless expressly stated otherwise.

In the above description, numerous specific details are set forth in order to provide a more thorough understanding of the disclosure. However, it will be apparent to one of ordinary skill in the art that the technology may be practiced without these specific details. In other instances, well-known features have not been described in detail to avoid unnecessarily complicating the description. Further, other embodiments not explicitly described above can be devised which do not depart from the scope of the claims as disclosed herein. Accordingly, the scope should be limited only by the attached claims.

What is claimed is:

1. An apparatus comprising:
an outer housing;
a tray assembly comprising a sliding tray and a tray insert, wherein the tray assembly is removable from the outer housing;
the tray insert secured to the sliding tray to form the tray assembly; and
the sliding tray configured to receive one or more cables routed within the outer housing with the tray insert.

2. The apparatus of claim 1, further comprising:
a sliding tray seal; and
a cable grommet seal of the sliding tray.

3. The apparatus of claim 1, further comprising:
the outer housing comprising an open end to receive the tray assembly.

4. The apparatus of claim 1, further comprising:
the outer housing comprising a first fastening member, wherein the first fastening member is structured to secure the tray assembly to the outer housing.

5. The apparatus of claim 1, further comprising:
the sliding tray comprising a second fastening member, wherein the second fastening member is structured to secure the tray assembly to the outer housing in conjunction with a first fastening member of the outer housing.

6. The apparatus of claim 1, further comprising:
the sliding tray comprising a flange demarcating an interior portion of the tray assembly from an exterior portion of the tray assembly.

7. The apparatus of claim 1, further comprising:
the sliding tray comprising a sliding tray seal at a proximal end of an interior portion of the tray assembly.

8. The apparatus of claim 1, further comprising:
the tray insert comprising a splice retainer and a coupler retainer.

9. The apparatus of claim 1, further comprising:
the tray insert comprising an attachment member to secure the tray insert to the sliding tray.

10. The apparatus of claim 1, further comprising:
the tray insert comprising an end retainer to secure cabling in conjunction with a perimeter wall of the tray insert.

11. A system forming a network interface device comprising:
a splice sleeve;
a coupler;
a tray assembly to which the splice sleeve and the couple are secured; and
an outer housing;
the tray assembly comprising a sliding tray and a tray insert, wherein the tray assembly is removable from the outer housing;
the tray insert secured to the sliding tray to form the tray assembly; and
the sliding tray configured to receive one or more cables routed within the outer housing with the tray insert.

12. The system of claim 11, further comprising:
a sliding tray seal; and
a cable grommet seal.

13. The system of claim 11, further comprising:
the outer housing comprising an open end to receive the tray assembly.

14. The system of claim 11, further comprising:
the outer housing comprising a first fastening member, wherein the first fastening member is structured to secure the tray assembly to the outer housing.

15. The system of claim 11, further comprising:
the sliding tray comprising a second fastening member, wherein the second fastening member is structured to secure the tray assembly to the outer housing in conjunction with a first fastening member of the outer housing.

16. The system of claim 11, further comprising:
the sliding tray comprising a flange demarcating an interior portion of the tray assembly from an exterior portion of the tray assembly.

17. The system of claim 11, further comprising:
the sliding tray comprising a sliding tray seal at a proximal end of an interior portion of the tray assembly.

18. The system of claim 11, further comprising:
the tray insert comprising a splice retainer and a coupler retainer.

19. The system of claim 11, further comprising:
the tray insert comprising an attachment member to secure the tray insert to the sliding tray.

20. A method comprising:
securing a cable to a tray insert in a sliding tray of a tray assembly, wherein the tray assembly comprises:
the sliding tray and a tray insert, wherein the tray assembly is removable from an outer housing;
the tray insert secured to the sliding tray to form the tray assembly; and
the sliding tray configured to receive one or more cables routed within the outer housing with the tray insert.
securing the tray assembly to the outer housing.
